(19) United States
(12) Patent Application Publication
(10) Pub. No.: US 2026/0113906 A1
(43) Pub. Date: Apr. 23, 2026

(54) COOLANT DISTRIBUTION UNIT CONTROL SYSTEM

(71) Applicant: LTI Holdings, Inc., Pleasanton, CA (US)

(72) Inventors: John R. Durbin, Spotsylvania, VA (US); Sukhvinder Kang, Pleasanton, CA (US)

(21) Appl. No.: 19/361,901

(22) Filed: Oct. 17, 2025

Related U.S. Application Data
(60) Provisional application No. 63/709,257, filed on Oct. 18, 2024.

(51) Int. Cl. H05K 7/20

(52) U.S. Cl. CPC H05K 7/20836; H05K 7/2079

(57) ABSTRACT

A coolant distribution unit includes a heat exchanger, a primary circuit fluidly coupled to a first side the heat exchanger and configured to convey a first coolant, a secondary circuit fluidly coupled to a second side of the heat exchanger, the secondary circuit including one or more pumps configured to convey a second coolant through the secondary circuit, and a controller configured to operate the one or more pumps in a plurality of modes, the plurality of modes including a first mode in which each of the one or more pumps are running at a maximum speed level, and a second mode in which at least one of the pumps is running at less than a maximum speed level.

### CROSS-REFERENCE TO RELATED APPLICATIONS

This application claims priority to U.S. Provisional Patent Application No. 63/709,257, filed Oct. 18, 2024, the entire content of which is incorporated herein by reference.

### SUMMARY

Computer system/data centers employ various cooling/heat dissipation methods to maintain environmental conditions suitable for information technology (IT) equipment (for example, servers, network switches, routers, storage devices, and other computing hardware) operation. Some data centers may utilize a liquid cooling system, where a liquid coolant is used to absorb heat generated from high-power equipment.

Liquid cooling systems include one or more coolant distribution units (CDUs) configured to actively distribute the liquid coolant to the various components of within the data center. CDUs include a primary flow loop/circuit configured to provide liquid coolant to a heat absorbing side of a heat exchanging technology (for example, a liquid-to-liquid heat exchanger) positioned within or outside of the CDU itself and a secondary flow loop/circuit configured to receive heated (“used”) liquid coolant at a heat dissipation side of the heat exchanging technology and return cooled liquid coolant to an equipment liquid cooling network. Within the cooling network of the secondary flow circuit, the liquid coolant is provided to a cooling module (for example, a single or series of cooling plates or heatsinks) proximate or within the information technology equipment via one or more feed lines, through which the liquid coolant absorbs heat from the equipment. The heated liquid coolant then flows, via one or more return feedlines, through a heat dissipating side of the heat exchanging technology within or outside the CDU, dissipating the heat from the liquid coolant. The cooled liquid coolant is then recirculated back to the information technology equipment via the one of more feed lines.

Within the primary flow loop, the used liquid coolant from the heat exchanging technology is cooled via one or more secondary cooling methods (for example, a chiller, cooling towers, etc.). The cooled liquid coolant is then recirculated back through the heat dissipation side of the heat exchanging technology.

CDUs operate through a pump system that circulates the liquid coolant through a network of pipes or channels. CDUs integrate additional components such as valves, filters, and monitoring mechanisms to optimize cooling efficiency and system reliability. Precisely calibrated valves allow for dynamic coolant distribution adjustments tailored to individual equipment/component needs, while filters are employed (for example, within the primary flow circuit) to sieve out impurities and contaminants. Equipped with sensors, CDUs continuously monitor coolant parameters like temperature, flow rate, and pressure levels, enabling real-time interventions to maintain peak thermal performance and reliability in complex environments.

For larger scale data centers, reliable CDU operation may be important for preventing overheating and ensuring performance and longevity of the equipment. Accordingly, embodiments described herein provide various control methods and systems for fault detection and failure mitigation for CDUs.

The present disclosure provides, in one aspect, a coolant distribution unit (CDU) including: a heat exchanger; a primary circuit fluidly coupled to a first side the heat exchanger and configured to convey a first coolant; a secondary circuit fluidly coupled to a second side of the heat exchanger, the secondary circuit including one or more pumps configured to convey a second coolant through the secondary circuit; a controller configured to operate the one or more pumps in a plurality of modes, the plurality of modes including a first mode in which each of the one or more pumps are running at a maximum speed level, and a second mode in which at least one of the pumps is running at less than a maximum speed level.

The present disclosure provides, in another aspect, a coolant distribution unit (CDU) electrically coupled to a building information management (BIM) system that monitors conditions of a building via a building automation and control (BAC) network, the CDU including: a heat exchanger system including a heat exchanger; a primary circuit fluidly coupled to a first side the heat exchanger and configured to convey a first coolant; a secondary circuit fluidly coupled to a second side of the heat exchanger, the secondary circuit including one or more pumps configured to convey a second coolant through the secondary circuit; and a controller configured to operate the one or more pumps and configured to send and receive one or more signals from the BIM system, and control operation of the heat exchanger system based on the one or more signals.

The present disclosure provides, in another aspect, a method of controlling a coolant distribution unit (CDU) and one or more systems of a building information management (BIM) system including: receiving, via a controller, an information from the BIM system; determining, via the controller, an efficiency of the one or mor systems; and adjusting, via the controller, an operation of one or more components of the CDU.

### BRIEF DESCRIPTION OF THE DRAWINGS

FIG. 1A illustrates a coolant distribution unit (CDU), according to some embodiments.

FIG. 1B illustrates the CDU of FIG. 1A, according to some embodiments.

FIG. 2A is a first portion of schematic diagram of the liquid coolant system of the CDU of FIG. 1A, according to some embodiments.

FIG. 2B is a second portion of the schematic diagram of the liquid coolant system of FIG. 2A, according to some embodiments.

FIG. 3 is a block diagram of an electronic controller of the CDU, according to some embodiments.

FIG. 4 illustrates an equipment cooling network and the CDU of FIG. 1A, according to some embodiments.

FIG. 5 is a data center cooling communications network including the CDU of FIG. 1A in accordance with some embodiments.

### DETAILED DESCRIPTION

Embodiments described herein relate to a coolant distribution unit (CDU).

Before any embodiments are explained in detail, it is to be understood that the embodiments are not limited in their application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

For ease of description, some or all of the example systems presented herein are illustrated with a single exemplar of each of its component parts. Some examples may not describe or illustrate all components of the systems. Other examples may include more or fewer of each of the illustrated components, may combine some components, or may include additional or alternative components.

Other aspects of the embodiments will become apparent by consideration of the detailed description and accompanying drawings.

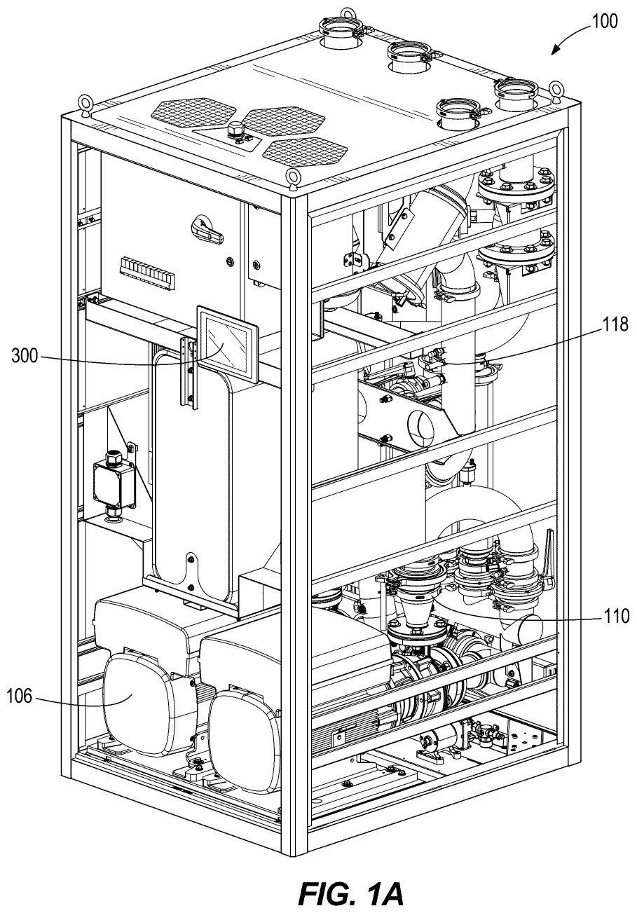

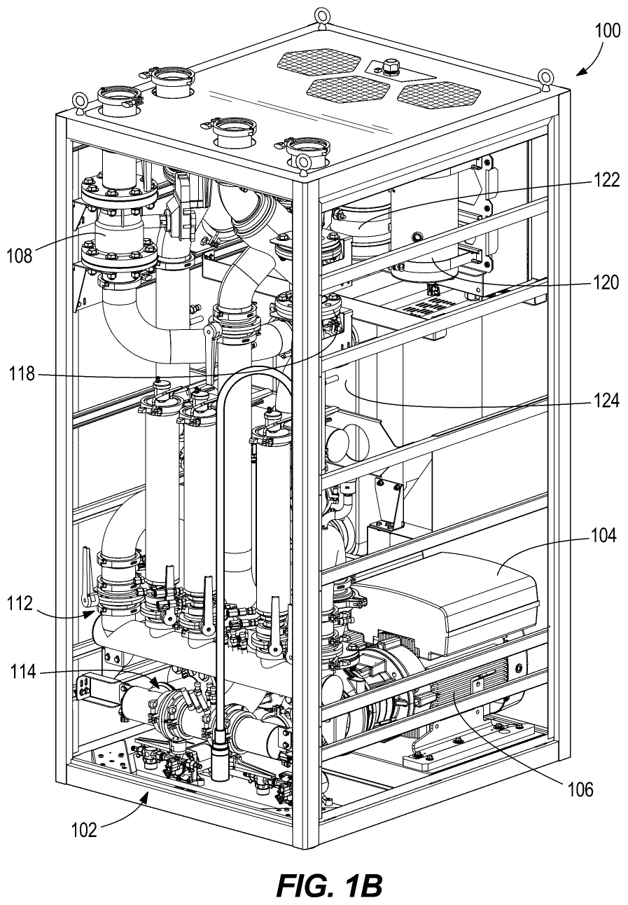

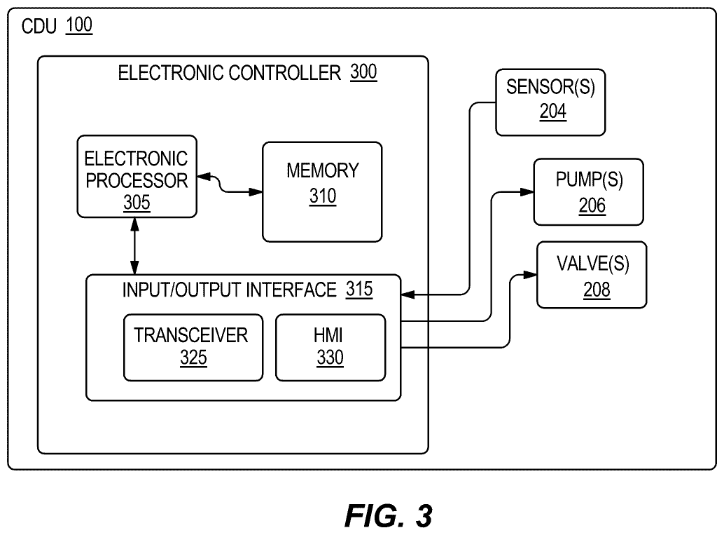

FIGS. 1A and 1B illustrate an example coolant distribution unit (CDU) 100. The CDU 100 includes, among other things, an electronic controller 300 (described in more detail below with respect to FIG. 3), a plurality of pumps (for example, fill and makeup pumps 102, a variable frequency drive (VFD) pump 104, and secondary pumps 106), a plurality of valves (for example, a primary control valve 108, a pump check valve 110, isolation valves 112), and a plurality of sensors (for example, temperature sensors 114, pressure sensors 116, flow meters 118). The CDU 100 also includes a reservoir 120, expansion tanks 122, and a liquid-to-liquid heat exchanger 124. The CDU also includes a housing (not shown).

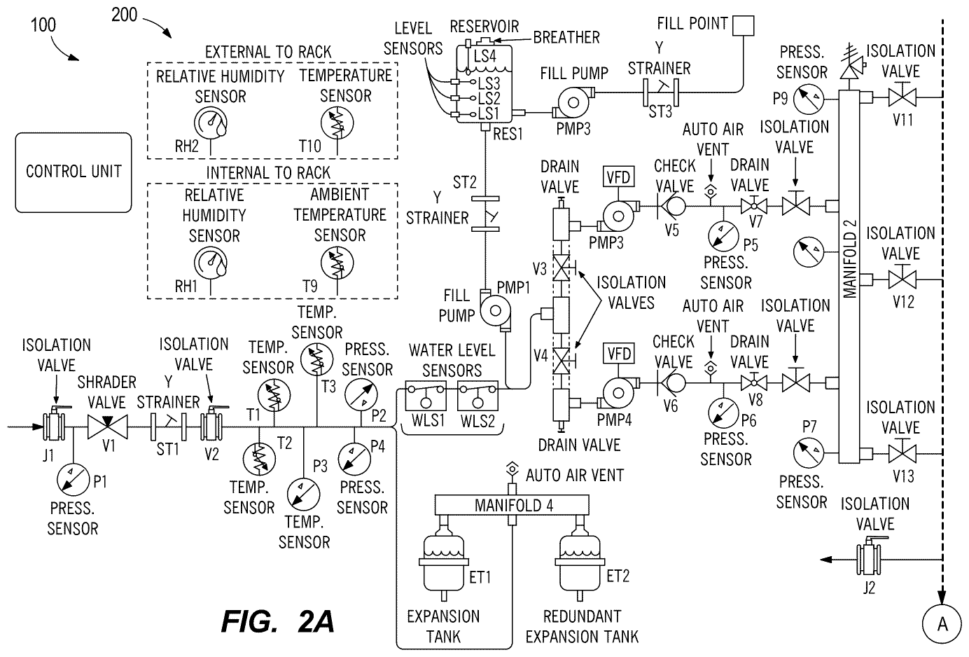

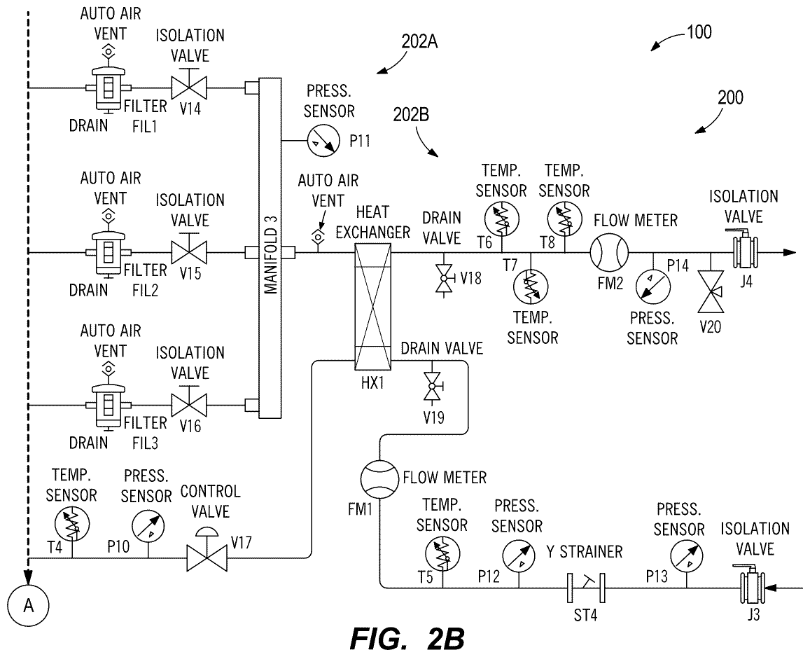

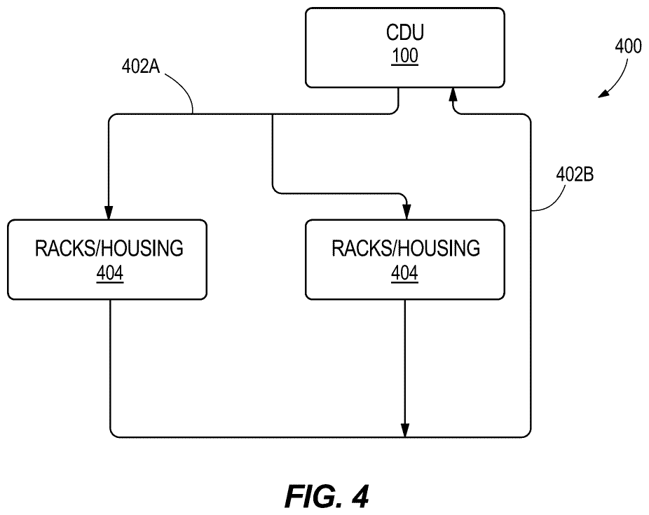

FIG. 2A-2B is a schematic diagram illustrating a fluid coolant flow system 200 of the CDU 100 in accordance with some embodiments. The system 200 comprises a primary fluid flow path (referred to herein as primary circuit 202A) of liquid coolant on a first (heat absorption) side of the heat exchanger 124 and a secondary flow path (referred to herein as secondary circuit 202B) of liquid coolant on a second (heat dissipation) side of the heat exchanger 124. The primary circuit 202A includes an input valve J3 and an output valve J2 (isolation valves 112 of FIGS. 1A and 1B). The secondary circuit 202B includes an input valve J1 and an output valve J4 (isolation valves 112 of FIGS. 1A and 1B). The heat exchanger 124 receives cooled liquid coolant from the primary circuit 202A to dissipate heat of the liquid coolant of the secondary circuit 202B received on the heat absorption side of the heat exchanger 124. The cooled liquid coolant of the secondary circuit 202B is then (at valve J4) output (for example, to an equipment coolant network 400, described below with respect to FIG. 4) for providing the recirculated coolant for heat dissipation of one or more information technology (IT) equipment (for example, servers, network switches, routers, storage devices, and other computing hardware). The heated liquid coolant from the network 400 is then returned to the system 200 (at valve J1). Meanwhile, the heated liquid coolant of the primary circuit 202A is recirculated and cooled (for example, via secondary cooling/heat transferring system (not shown) that receives the heated liquid coolant output at valve J2 and provides cooled liquid coolant back to the CDU 100 at the input of valve J3). The CDU 100 may include additional components/subsystems for additional cooling of the liquid coolant in some embodiments.

FIG. 4 is an example equipment cooling network 400 for cooling a plurality of IT equipment in accordance with some embodiments. The equipment cooling network 400 includes a feed line 402A that is configured to receive cooled liquid coolant output from the CDU 100 (i.e. the output of valve J4 of FIG. 2B). The feed line 402A is connected to one or more secondary pipes (not shown) of equipment racks/housing 404, each of the racks/housing 404 including one or more IT equipment. The secondary pipes of the racks/housing 404 may run alongside one or more heat transferring surfaces of the rack/housing 404 (or of the IT equipment itself) to absorb heat generated from the respective IT equipment. From each of the racks/housing 404, the warmed coolant returned to the CDU 100 (at the input of valve J3 of FIG. 2B) via return line 402B to be re-cooled and recirculated within the equipment cooling network 400.

Returning to FIG. 2A-2B, as illustrated, the primary circuit 202A includes a plurality of valves V17, V19, J2, and J3 and sensors (for example, temperature sensors T4 and T5, pressure sensors P10, P12, and P13, and flow meter FM1. The secondary circuit 202B also includes a plurality of valves V1-V16, V18, V20, J1, and J4, pumps PMP1-PMP4, and sensors (for example, temperature sensors T1-T3 and T6-T8, pressure sensors P1-P9, P11, and P14, and flow meter FM2. The controller 300 is communicatively coupled to and controls operation of each of the plurality of valves V1-V20, and pumps PMP1-PMP4 based on sensor information from one or more of the various sensors of the system 200. The controller 300 may also receive sensor information regarding environmental information within the housing of the CDU 100 (for example, via a relative humidity sensor RH1 and an ambient temperature sensor T9) and outside of the housing of the CDU 100 (for example, via a relative humidity sensor RH2 and a temperature sensor T10). For ease of description, the sensors of the flow system 200 are collectively referred to herein as the plurality of sensors 204, the valves of the flow system 200 are collectively referred to herein as the plurality of valves 208, and the pumps of the flow system 200 are collectively referred to herein as the plurality of pumps 206. In some embodiments, one or more different types of sensors of the system 200 (and functionality thereof) may be combined as a single sensor (for example, a combined temperature and humidity sensor, a combined pressure and water flow sensor, and the like). The system 200 may include additional or fewer sensors than those illustrated in FIG. 2A-2B.

The fluid coolant flow system 200 may include additional components (for example, filters FIL1-FIL3, strainers ST1-ST4, auto air vents, and pressure relief valves) which, for sake of brevity, are not described herein in detail.

FIG. 3 is a block diagram of the electronic controller 300 of the CDU 100 in accordance with some embodiments. The electronic controller 300 includes a plurality of electrical and electronic components that facilitate power, operation control, and protection to the components and modules within the electronic controller 300. The electronic controller 300 includes, among other things, an electronic processor 305 (such as a programmable electronic microprocessor, microcontroller, or similar device), a memory 310 (for example, non-transitory, computer readable memory), and an input/output interface 315. The electronic processor 305 is communicatively connected to the memory 310 and the input/output interface 315. The electronic processor 305, in coordination with the memory 310 and the input/output interface 315, is configured to implement, among other things, the methods described herein. It should be understood that some or all of the components, including additional components, of the controller 300 may be remote/dispersed from each other within the CDU 100 and/or remote from the CDU 100.

The memory 310 may be made up of one or more non-transitory computer-readable media and includes at least a program storage area and a data storage area. The program storage area and the data storage area can include combinations of different types of memory, such as read-only memory (“ROM”), random access memory (“RAM”), flash memory, or other suitable memory devices. The electronic processor 305 is coupled to the memory 310 and the input/output interface 315.

The electronic processor 305 sends and receives information (for example, from the memory 310 and/or the input/output interface 315) and processes the information by executing one or more software instructions or modules, capable of being stored in the memory 310, or another non-transitory computer readable medium. The software can include firmware, one or more applications, program data, filters, rules, one or more program modules, and other executable instructions. The electronic processor 305 is configured to retrieve from the memory 310 and execute, among other things, software for automatic detection/prediction of an anomaly within the CDU 100 and for performing methods as described herein.

In some instances, the electronic controller 300 may be implemented in several independent controllers (for example, programmable electronic controllers) each configured to perform specific functions or sub-functions. For example, one or more components of the controller 300 may be remote from the CDU 100 (for example, part of a remote server, which is not shown, communicatively coupled to the CDU 100). Additionally, the electronic controller 300 may contain sub-modules that include additional electronic processors, memory, or circuits for handling input/output functions, processing of signals, and application of the methods listed below. In other instances, the electronic controller 300 includes additional, fewer, or different components. Thus, the programs may also be distributed among one or more processors.

The input/output interface 315 transmits and receives information from devices external to the electronic controller 300 (for example, over one or more wired and/or wireless connections), for example, components of the CDU 100. The input/output interface 315 receives input (for example, from the plurality of sensors 204), provides system output (for example, to one or more of the plurality of valves 208 and/or the plurality of pumps 206, the transceiver 325 and/or the HMI 330, etc. ,). The input/output interface 315 may also include other input and output mechanisms, which for brevity are not described herein and which may be implemented in hardware, software, or a combination of both.

In some instances, the controller 300 further includes the transceiver 325 and/or the human machine interface (HMI) 330. The transceiver 325 includes a radio transceiver communicating data over one or more wireless communications networks (for example, cellular networks, satellite networks, land mobile radio networks, etc.). The transceiver 325 also provides wireless communications within the vehicle using suitable network modalities (for example, Bluetooth™, near field communication (NFC), Wi-Fi™, and the like). Accordingly, the transceiver 325 communicatively couples the electronic controller 300 and other components of the CDU 100 with networks or electronic devices both inside and outside the CDU 100. For example, the electronic controller 300, using the transceiver 325, can communicate with a one or more devices (for example, other CDUs 100) over a communications system (not shown) to send and receive data, commands, and other information. The transceiver 325 includes other components that enable wireless communication (for example, amplifiers, antennas, baseband processors, and the like), which for brevity are not described herein and which may be implemented in hardware, software, or a combination of both. Some instances include multiple transceivers or separate transmitting and receiving components (for example, a transmitter and a receiver) instead of a combined transceiver.

The HMI 330 provides visual output, such as, for example, graphical indicators (i.e., fixed or animated icons), lights, colors, text, images, combinations of the foregoing, and the like. The HMI 330 includes a suitable display mechanism for displaying the visual output, such as, for example, an instrument cluster, a center console display screen (for example, a touch screen, or other suitable mechanisms), etc. In some instances, the HMI 330 displays a graphical user interface (GUI) (for example, generated by the electronic processor 305 and presented on a display screen) that enables a driver or passenger to interact with the CDU 100. The HMI 330 may also provide audio output to the driver such as a chime, buzzer, voice output, or other suitable sound through a speaker included in the HMI 330 or separate from the HMI 330. In some instances, HMI 330 provides a combination of visual and audio outputs.

As will be described in further detail below, in some instances the memory 310 includes, among other things, computer executable instructions for component and measurement fault detection and mitigation. In some instances, the computer executable instructions include instructions for training a deep learning system to detect/predict one or more anomalies related to one or more components of the CDU 100.

In some instances, the electronic controller 300 uses one or more machine learning methods (for example, artificial intelligence algorithms) to analyze sensor information from the sensors 204 to identify/predict anomalies within the CDU 100 (as described herein). Machine learning generally refers to the ability of a computer program to learn without being explicitly programmed. In some instances, a computer program (for example, a learning engine) is configured to construct an algorithm based on inputs. Supervised learning involves presenting a computer program with example inputs and their desired outputs. The computer program is configured to learn a general rule that maps the inputs to the outputs from the training data it receives. Example machine learning engines include decision tree learning, association rule learning, artificial neural networks, classifiers, edge computing, inductive logic programming, support vector machines, clustering, Bayesian networks, reinforcement learning, representation learning, similarity and metric learning, sparse dictionary learning, and genetic algorithms. Using these approaches, a computer program can ingest, parse, and understand data and progressively refine algorithms for data analytics.

The system performance of the flow system 200 is dependent on, among other things, proper operation of the pumps 206. In some embodiments, each of the pumps includes a respective pump fault sensor (for example, a fault sensor integrated into the pump). In instances where the pump fault sensor indicates a fault, the sensor is configured to provide a fault signal to the electronic controller 300. The electronic controller 300, in response, may accordingly generate an alert to a user (for example, via the HMI 330), halt or adjust an operation of one or more of the pumps 206, or both. However, there may be instances where the pump fault sensor itself is faulty. In such instances, the pump fault sensor may output the fault signal to the controller 300 even when the respective pump is operating normally. This may result in the controller 300 to provide false alerts and/or unnecessary modifications/shutdowns of one or more operations of the system 200.

Thus, it may be desirable for the electronic controller 300 to perform additional steps to verify whether or not one or more of the pumps are operating properly including evaluating an accuracy of a measurement from one or more of the sensors 204.

In some embodiments, the electronic controller 300 is configured to operate one or more of the pumps 206 in different operational modes. For example, in some embodiments, the controller 300 is configured to operate one or more of the pumps 206 in a green or efficiency mode. The controller 300, for example, may evaluate, for a particular operating point (for example, a particular flow and pressure), for a given equipment cooling network 400, a plurality of different pump operation configurations of the plurality of pumps 206. Each of the different pump operation configurations includes one or more of the pumps 206 operating at one or more different operational levels (for example, a plurality of different speed levels of the pump). The controller 300 determines, from the plurality of different pump operation configurations, a pump operation configuration with the least energy usage that meets the particular operating point. For example, the controller 300 may evaluate whether the system 200 is able to meet the particular operating point while operating two or more pumps at a less than maximum speed level (a first pump operation configuration) than a single pump at a maximum speed level (a second pump operation configuration), which may demand more energy (energy consumption) than the first pump operation configuration. As another example, in some embodiments, the controller 300 is configured to operate at least one of the pumps 206 in a life-extending mode. For example, the controller 300 may be configured to determine and control an operation of the pump so as to extend a service life of the pump. The service life may be determined by the controller 300 based on, for instance, the time the pump has been running and the speed at which the pump has been running. Other conditions may also be considered, such as temperature, pump current, etc. In some embodiments, the controller 300 may send a signal to, for instance, a human machine interface indicating service of a pump is required, regardless of sensor information received from one or more sensors.

In some embodiments, the controller 300 is configured to operate the CDU 100 in an energy conservation mode. For example, the electronic controller 300 may be configured to determine when coolant to the secondary circuit 202B is not being circulated through the equipment cooling network 400 (for example, due to the IT equipment being taken off-line, shut down for maintenance, etc.). In response, the electronic controller 300 may be configured to stop pumping or reduce pumping of the coolant through the secondary circuit 202B (for example, via one or more of the pumps 106). The control valve V17 of the primary circuit 202A may, in response to the reduced pumping of secondary circuit 202B, close. While in the energy conservation mode, the electronic controller 300 may intermittently operate one or more of the pumps 106 while operating the CDU 100 in the energy conservation mode (for example, to prevent build-up of contaminants and/or chemical deposits within the secondary circuit 202B).

In some embodiments, the CDU 100 may be configured in a pod with a plurality of CDUs. The controller 300 of one CDU may be configured to communicate with the controllers of each of the CDUs of the pod to coordinate control of the CDUs of the pod to operate all of the CDUs in a green mode, or in an efficiency mode to conserve energy, optimize efficiency, etc.

In some embodiments, the electronic processor 305 is configured to monitor a total run/operation time of one or more components (for example, one or more of the pumps 206 and/or valves 208 of the system 200). In response to the measured operation time exceeding a predetermined time threshold, the electronic processor 305 may be configured to generate an alert to a user (for example, via the HMI 330) to alert the user that the component may need to be replaced. In some embodiments, the operation time is reduced or increased by a factor derived from a performance operation of the component. For example, if a pump operates for X number of hours at a 55% maximum speed, the operation time counted/determined by the electronic processor 305 may be reduced by a predetermined factor corresponding to the 55% maximum speed.

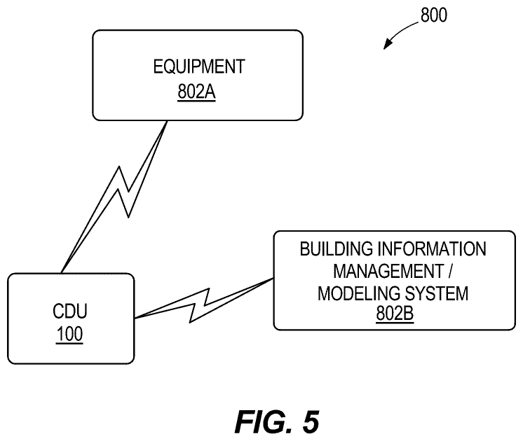

As previously described above (for example, with respect to FIG. 3), in some embodiments, the electronic controller 300 is configured to communicate with one or more electronic devices/components outside of the CDU 100 (for example, via a wired communications connection or a wireless connection via the transceiver 325). FIG. 5 is an example of a data center cooling communications network 800 including the CDU 100, an IT equipment 802A, and a building information management/modelling (BIM) system 802B. Both the IT equipment 802A and the BIM system 802B are communicatively coupled to the CDU 100 via a suitable wired connection, wireless connection, or some combination of both. Wireless communications may be implemented using a wide area network, for example, the Internet (including public and private IP networks), a Long-Term Evolution (LTE) network, a 4G network, 5G network and one or more local area networks, for example, a Bluetooth™ network or Wi-Fi network, and combinations or derivatives thereof.

The IT equipment 802A is an electronic equipment cooled via the equipment cooling network 400 (for example, via the racks/housing 404 as described above with respect to FIG. 4) coupled to the CDU 100. For ease of description, the communications network 800 is described in terms of a single IT equipment 802A. It should be understood that, in some embodiments, the network 800 includes more than one IT equipment 802A is communicatively coupled to the CDU 100. It should also be understood that the network 800 may include more than one CDU 100, each CDU 100 being communicatively coupled to a respective one or more IT equipment 802A.

The BIM system 802B includes one or more building automation and control (BAC) networks that allow for communication therebetween. Such systems may include communications related to, for example, heating, ventilating, and air-conditioning control (HVAC), lighting control, access control, and fire detection systems of the data center.

In some embodiments, the CDU 100 is configured to receive information from the IT equipment 802A (for example, temperature information, operational information, etc.) and adjust operation of one or more of the pumps 206 and/or valves 208, for example, to optimize energy use of the CDU 100 based on the received information. Additionally or alternatively, in some embodiments, the CDU 100 is configured to adjust operation of one or more of the pumps 206 and/or valves 208 based on information received from the BIM system 802B.

In some embodiments, the electronic controller 300 (and components thereof) are disposed on a single circuit board.

In some embodiments, the CDU 100 includes one or more of a harmonic filter disposed between an electrical supply system (not shown) of the system 200 and at least one component of the system 200 (for example, one or more motors (not shown) of one or more of the pumps 206). The controller 300, in some embodiments, is configured to monitor an electrical characteristic of one or more components of the system 200 (for example, a voltage, a current, etc.) via the harmonic filter. The controller 300 is configured to detect, based on the monitored electrical characteristic, a noise factor (including one or more harmonic signals) within a power signal between the electrical supply system and the component. The controller 300 is configured to, based on the monitored electrical characteristic, produce an inverse signal (inverse of the noise factor) and apply the inverse signal to the power signal, to reduce or cancel out the noise factor within the power signals.

In some embodiments, the controller 300 is further configured to operate one or more of the pumps 206 (for example, one or more EPICV pumps) of the system 200 according to a proportional-integral-derivative (PID) loop (for example, based on a detected pressure within the system 200).

What is claimed is:

1. A coolant distribution unit (CDU) comprising:
a heat exchanger;
a primary circuit fluidly coupled to a first side the heat exchanger and configured to convey a first coolant;
a secondary circuit fluidly coupled to a second side of the heat exchanger, the secondary circuit including one or more pumps configured to convey a second coolant through the secondary circuit;
a controller configured to operate the one or more pumps in a plurality of modes, the plurality of modes including a first mode in which each of the one or more pumps are running at a maximum speed level, and a second mode in which at least one of the pumps is running at less than a maximum speed level.

2. The CDU of claim 1, wherein in the second mode, each of the pumps is running at less than a maximum speed level.

3. The CDU of claim 1, wherein the controller changes the operation from the first mode to the second mode based on an operating condition of the primary circuit or the secondary circuit.

4. The CDU of claim 3, wherein the operating condition is a temperature of the coolant.

5. The CDU of claim 1, wherein the controller determines a service life of the one or more pumps and changes the mode from the first mode to the second mode to prolong the life of the pump.

6. The CDU of claim 5, wherein the service life is determined based on a time the pump has been running and a speed at which the pump has been running.

7. The CDU of claim 6, wherein the controller sends a signal indicating the pump requires service when a service life has been reached.

8. The CDU of claim 1, wherein the controller determines an efficiency of the CDU and changes from the first mode to the second mode based on the efficiency.

9. The CDU of claim 8, wherein the efficiency of the CDU is based on an energy consumption of the one or more pumps.

10. The CDU of claim 1, wherein the controller determines a first energy consumption of the pumps in the first mode and a second energy consumption of the pumps in the second mode, and selects one of the first mode or second mode based on a lower of the first energy consumption and the second energy consumption.

11. A coolant distribution unit (CDU) electrically coupled to a building information management (BIM) system that monitors conditions of a building via a building automation and control (BAC) network, the CDU comprising:
a heat exchanger system including
a heat exchanger;
a primary circuit fluidly coupled to a first side the heat exchanger and configured to convey a first coolant;
a secondary circuit fluidly coupled to a second side of the heat exchanger, the secondary circuit including one or more pumps configured to convey a second coolant through the secondary circuit; and
a controller configured to operate the one or more pumps and configured to send and receive one or more signals from the BIM system, and control operation of the heat exchanger system based on the one or more signals.

12. The CDU of claim 11, wherein the controller receives one or more signals indicating the condition of the building and controls operation of one of more of the pumps based on the signal received.

13. The CDU of claim 12, wherein the controller sends a signal to the BIM to control operation of another system in the building when a secondary coolant flow through the secondary circuit changes.

14. The CDU of claim 12, wherein the condition is one of a heating, ventilating, and air-conditioning control (HVAC) condition, a lighting control condition, an access control condition, and a fire detection system condition.

15. The CDU of claim 11, wherein the controller receives a power supply from the building, monitors a characteristic of the power supply, and applies a filter to the power supply.

16. The CDU of claim 15, wherein the filter is a harmonic filter.

17. The CDU of claim 11, wherein the BIM system includes an information technology equipment including one or more servers, and the controller is configured to control operation of the heat exchanger system based on an information received from the information technology equipment.

18. A method of controlling a coolant distribution unit (CDU) and one or more systems of a building information management (BIM) system comprising:
receiving, via a controller, an information from the BIM system;
determining, via the controller, an efficiency of the one or mor systems; and
adjusting, via the controller, an operation of one or more components of the CDU.

19. The method of claim 18, wherein the information is a condition of an IT equipment.

20. The method of claim 19, wherein the condition is a temperature condition.
